(19) United States
(12) Patent Application Publication
(10) Pub. No.: US 2012/0075781 A1
(43) Pub. Date: Mar. 29, 2012

(54) Flat panel display apparatus and method of manufacturing the same

(76) Inventors: Sung-Soo Koh, Yongin-City (KR); Oh-Seob Kwon, Yongin-City (KR); Byung-Uk Han, Yongin-City (KR); Jung-Jun Im, Yongin-City (KR); Jae-Sang Ro, Seoul (KR); Seog-Young Lee, Seoul (KR); Won-Eui Hong, Seoul (KR)

(21) Appl. No.: 13/137,908

(22) Filed: Sep. 21, 2011

(30) Foreign Application Priority Data
Sep. 24, 2010 (KR) 10-2010-0092855

(51) Int. Cl. H05K 7/00; H01J 9/26

(52) U.S. Cl. 361/679.01; 445/25

(57) ABSTRACT

A flat panel display apparatus with improved sealing characteristics, and a method of manufacturing the same. The flat panel display apparatus includes a substrate; a display unit disposed on the substrate; a sealing substrate disposed to face the display unit; a sealing member disposed between the substrate and the sealing substrate to surround the display unit; a wiring unit disposed between the substrate and the sealing substrate to overlap the sealing member; a first protective layer disposed between the sealing member and the wiring unit; and inlets formed to be electrically connected to an external power source and the wiring unit to apply a voltage to the wiring unit.

### BACKGROUND

1. Field

Embodiments relate to a flat panel display apparatus, and a method of manufacturing the same. More particularly, the embodiments relate to a flat panel display apparatus with improved sealing characteristics, and a method of manufacturing the same.

2. Description of the Related Art

Currently, display apparatuses are being replaced by portable thin flat panel display apparatuses. Flat panel display apparatuses, such as organic light emitting display apparatuses and liquid crystal display apparatuses, attract people due to their excellent image quality characteristics.

In a flat panel display apparatus, a display unit is disposed on a substrate and a sealing substrate is disposed on the display unit to protect the display unit. A sealing member is disposed between the substrate and the sealing substrate. The display unit is disposed between the substrate and the sealing substrate and protected from the external environment.

The sealing member may be formed by using various methods. For example, the sealing member is formed by disposing a material for forming the sealing member between the substrate and the sealing substrate. Then, the material is melted and cured by using heat. The substrate and the sealing substrate are combined with each other.

The quality of the flat panel display apparatus is influenced by characteristics of the display unit. The display unit may be easily damaged by moisture, gases, and other impurities provided from outside the flat panel display apparatus.

A process of forming the sealing member disposed between the substrate and the sealing substrate has been a challenge. Thus, effective sealing of the display unit has been difficult.

### SUMMARY

Embodiments are therefore directed to a flat panel display, and a method of manufacturing the same which substantially overcomes one or more of the problems due to the limitations and disadvantages of the related art.

It is therefore a feature of an embodiment to provide a flat panel display apparatus capable of easily improving its sealing characteristics.

It is therefore another feature of an embodiment to provide a method of manufacturing the flat panel display apparatus capable of easily improving its sealing characteristics.

At least one of the above and other features and advantages may be realized by providing a flat panel display apparatus including a substrate; a display unit disposed on the substrate; a sealing substrate disposed to face the display unit; a sealing member disposed between the substrate and the sealing substrate to surround the display unit; a wiring unit disposed between the substrate and the sealing substrate to overlap the sealing member; a first protective layer disposed between the sealing member and the wiring unit; and inlets formed to be electrically connected to an external power source, wherein the inlets apply a voltage to the wiring unit.

The flat panel display apparatus may further include a second protective layer disposed between the substrate and the wiring unit.

The flat panel display apparatus may further include a third protective layer disposed between the sealing substrate and the sealing member.

The first protective layer may be formed to correspond to side surfaces of the wiring unit.

The first protective layer may extend to contact the substrate.

The first protective layer may extend to be disposed on the inlets.

The wiring unit may be formed on the substrate, and the sealing member may be disposed between the wiring unit and the sealing substrate.

The sealing member may include frit.

The display unit may include an organic light emitting device.

At least one of the above and other features and advantages may also be realized by providing a method of manufacturing a flat panel display apparatus, the method including preparing a substrate; disposing a display unit on the substrate; disposing a sealing substrate to face the display unit; forming a sealing member between the substrate and the sealing substrate to surround the display unit; disposing a wiring unit between the substrate and the sealing substrate to overlap the sealing member; disposing a first protective layer between the sealing member and the wiring unit; and forming inlets to be electrically connected to an external power source and the wiring unit to apply a voltage to the wiring unit, wherein the forming of the sealing member includes disposing a material for forming the sealing member between the substrate and the sealing substrate; electrically connecting the inlets to the power source; applying a voltage from the power source to the wiring unit to generate heat from the wiring unit; and melting and curing the sealing member by using the generated heat.

Forming the sealing member may include frit.

### BRIEF DESCRIPTION OF THE DRAWINGS

The above and other features and advantages of the inventive concept will become more apparent by describing in detail exemplary embodiments thereof with reference to the attached drawings in which:

FIG. 1 is a plan view of a flat panel display apparatus according to an embodiment;

FIG. 2 is a cross-sectional view taken along a line II-II illustrated in FIG. 1;

FIG. 3 is a magnified view of a portion X illustrated in FIG. 2;

FIG. 4 is a plan view of a process of applying power to form a sealing member in a method of manufacturing the flat panel display apparatus illustrated in FIG. 1;

FIG. 5 is a cross-sectional view of a flat panel display apparatus according to another embodiment;

FIG. 6 is a cross-sectional view of a flat panel display apparatus according to another embodiment;

FIG. 7 is a cross-sectional view of a flat panel display apparatus according to another embodiment; and

FIG. 8 is a cross-sectional view of a flat panel display apparatus according to another embodiment.

### DETAILED DESCRIPTION

Korean Patent Application No. 10-2010-0092855, filed on Sep. 24, 2010, in the Korean Intellectual Property Office, and entitled: “Flat Panel Display Apparatus and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be through and complete, and will fully convey the scope of the inventive concept to those skilled in the art.

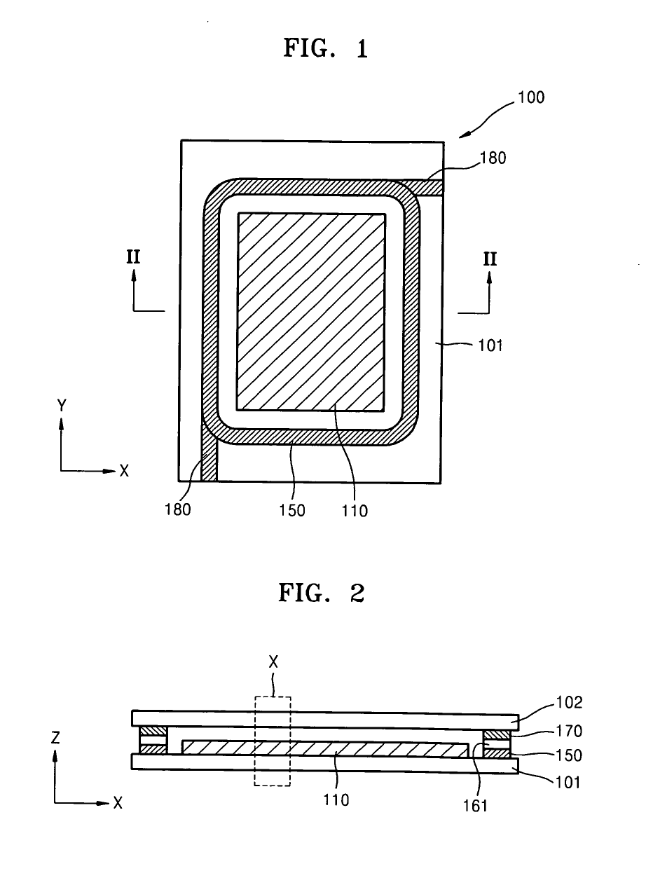

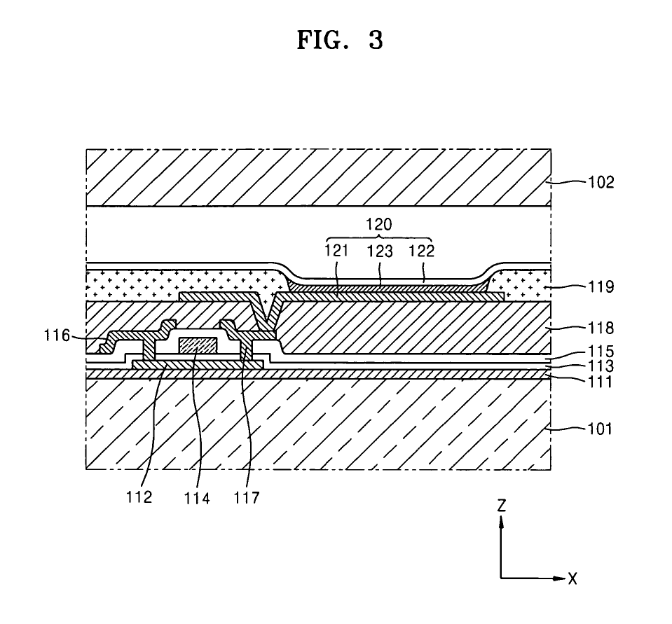

FIG. 1 is a plan view of a flat panel display apparatus 100 according to an embodiment. FIG. 2 is a cross-sectional view taken along a line II-II illustrated in FIG. 1. FIG. 3 is a magnified view of a portion X illustrated in FIG. 2. For explanation and clarity, a sealing substrate 102 is not illustrated in FIG. 1.

Referring to FIGS. 1 through 3, the flat panel display apparatus 100 includes a substrate 101, a display unit 110, the sealing substrate 102, a wiring unit 150, a sealing member 170, a first protective layer 161, and inlets 180.

The substrate 101 may be formed of a transparent glass material mainly including SiO₂. However, the substrate 101 is not limited thereto and may be formed of a transparent plastic material. The transparent plastic material for forming the substrate 101 may be an insulating organic material selected from the group consisting of polyethersulfone (PES), polyacrylate (PAR), polyetherimide(PEI), naphthalatepolyethyelene naphthalate (PEN), polyethyelene teterephthalate (PET), polyphenylene sulfide (PPS), polyarylate, polyimide, polycarbonate (PC), cellulose triacetate (TAC), and cellulose acetate propionate (CAP).

The display unit 110 is disposed on the substrate 101. The display unit 110 may be of various types. Although the display unit 110 includes an organic light emitting device in FIGS. 1 through 3, the current embodiment is not limited thereto. The display unit 110 may include a liquid crystal device.

The sealing substrate 102 is disposed to face the display unit 110. The sealing member 170 is disposed between the substrate 101 and the sealing substrate 102. The sealing member 170 is formed to surround the display unit 110. The sealing member 170 allows the substrate 101 and the sealing substrate 102 to be easily combined with each other. The sealing member 170 may include frit.

The wiring unit 150 is formed to overlap the sealing member 170. Thus, the wiring unit 150 is formed to surround the display unit 110. The wiring unit 150 may be formed of various conductive materials.

The first protective layer 161 is disposed between the wiring unit 150 and the sealing member 170. The wiring unit 150 is formed on the substrate 101, the first protective layer 161 is formed on the wiring unit 150, the sealing member 170 is formed on the first protective layer 161, and the sealing substrate 102 is disposed on the sealing member 170.

The first protective layer 161 includes an insulator, e.g., an oxide.

The first protective layer 161 is disposed between the wiring unit 150 and the sealing member 170 to allow the wiring unit 150 and the sealing member 170 to easily bond to each other. The first protective layer 161 is disposed to prevent separation between a material, e.g., frit, and a conductive material, e.g., metal. The material is used for forming the sealing member 170. The conductive material is used for forming the wiring unit 150.

After a material, e.g., frit, for forming the sealing member 170 is disposed and the sealing member 170 is formed, a drying and sintering process is performed at a high temperature. The first protective layer 161 protects and prevents damage to the wiring unit 150 during the high-temperature process.

The inlets 180 are formed to be connected to the wiring unit 150. The inlets 180 are formed at ends of the wiring unit 150. The inlets 180 are formed to be electrically connected to an external power source (not shown).

The first protective layer 161 is disposed on the inlets 180. Thus, upper portions of the inlets 180 are prevented from contacting and being oxidized due to moisture and air.

In the process of forming the sealing member 170, the external power source may be connected to the inlets 180. A voltage may be applied to the wiring unit 150 via the inlets 180 to generate joule heat from the wiring unit 150. The material for forming the sealing member 170 may be melted and cured by the joule heat. The inlets 180 are formed of the same material as the wiring unit 150.

The display unit 110 may be various types. The display unit 110 uses an organic light emitting device in FIGS. 1 through 3. The display unit 110 will now be described in detail with reference to FIG. 3.

A buffer layer 111 is formed on the substrate 101. The buffer layer 111 may provide a flat surface on the substrate 101 and may prevent penetration of moisture and impurities into the substrate 101.

An active layer 112 having a predetermined pattern is formed on the buffer layer 111. The active layer 112 may be formed of an organic semiconductor or an inorganic semiconductor such as amorphous silicon or polysilicon. The active layer 112 includes a source region, a drain region, and a channel region.

The source and drain regions may be formed by doping the active layer 112, formed of amorphous silicon or polysilicon, with an impurity. A p-type semiconductor may be obtained if the active layer 112 is doped with a group III element, e.g. boron (B). An n-type semiconductor may be obtained if the active layer 112 is doped with a group V element, e.g. nitrogen (N).

A gate insulating layer 113 is formed on the active layer 112. A gate electrode 114 is formed on a predetermined region of the gate insulating layer 113. The gate insulating layer 113 is used to insulate the active layer 112 from the gate electrode 114. The gate insulating layer 113 may be formed of an organic material or an inorganic material such as SiNx or SiO₂.

The gate electrode 114 may be formed of a metal such as gold (Au), silver (Ag), copper (Cu), nickel (Ni), platinum (Pt), palladium (Pd), aluminum (Al), or molybdenum (Mo), or a metal alloy such as an Al:Nd alloy or a Mo:W alloy. However, the gate electrode 114 is not limited thereto, and may be formed of various materials. For example, the various metals may be formed in consideration of characteristics such as adhesion, planarization, electric resistance, processability, and so on. The gate electrode 114 is connected to a gate line (not shown) for applying an electrical signal.

An interlayer insulating layer 115 is formed on the gate electrode 114. The interlayer insulating layer 115 and the gate insulating layer 113 are formed, exposing the source and drain regions of the active layer 112. A source electrode 116 and a drain electrode 117 also are exposed. The source electrode 116 and the drain electron 117 contact the exposed source and drain regions of the active layer 112.

The source and drain electrodes 116 and 117 may be formed of a metal such as Au, Pd, Pt, Ni, rhodium (Rh), ruthenium (Ru), iridium (Ir), osmium (Os), Al, or Mo, or a metal alloy such as an Al:Nd alloy or an MoW alloy, but are not limited thereto.

A passivation layer 118 is formed to cover the source and drain electrodes 116 and 117. The passivation layer 118 may be formed as an inorganic insulating layer and/or an organic insulating layer. The inorganic insulating layer may be formed of SiO₂, SiNx, SiON, Al₂O₃, TiO₂, Ta₂O₅, HfO₂, ZrO₂, barium strontium titanate (BST), or lead zirconate titanate (PZT). The organic insulating layer may be formed of a general-use polymer such as polymethylmethacrylate (PMMA) or polystyrene (PS), a polymer derivative containing a phenol group, an acryl-based polymer, an imide-based polymer, an arylether-based polymer, an amide-based polymer, a fluorine-based polymer, a p-xylene-based polymer, a vinyl alcohol-based polymer, or a mixture thereof. The passivation layer 118 may be a stack of the organic and inorganic insulating layers.

The passivation layer 118 is formed, exposing the drain electrode 117. An organic light emitting device 120 is formed to be connected to the exposed drain electrode 117. The organic light emitting device 120 includes a first electrode 121, a second electrode 122, and an intermediate layer 123. The first electrode 121 contacts the drain electrode 117.

The intermediate layer 123 includes an organic light emitting layer and generates visible light if a voltage is applied to the first and second electrodes 121 and 122.

A pixel defining layer 119 is formed on the first electrode 121 by using an insulator. A predetermined opening is formed in the pixel defining layer 119 to expose the first electrode 121. The intermediate layer 123 is formed on the exposed first electrode 121. The second electrode 122 is formed to be connected to the intermediate layer 123.

The first and second electrodes 121 and 122 have polarities of an anode and a cathode. The embodiment also includes first and second electrodes 121 and 122 have polarities of a cathode and an anode.

The sealing substrate 102 is disposed on or above the second electrode 122.

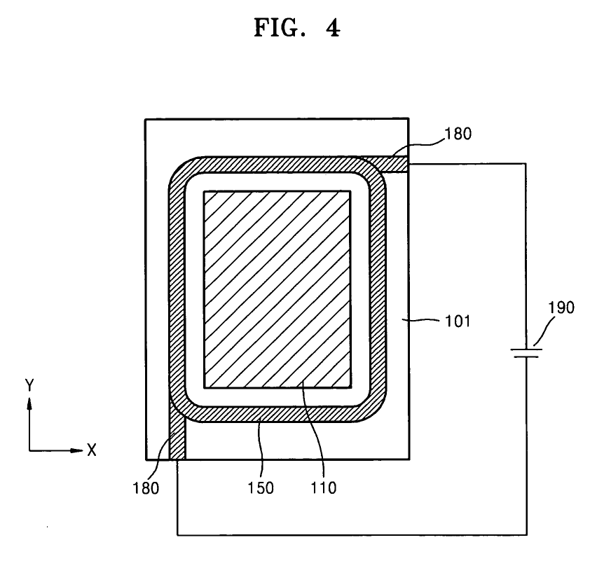

FIG. 4 is a plan view of a process of applying power to form the sealing member 170 in a method of manufacturing the flat panel display apparatus 100 illustrated in FIG. 1.

The method of manufacturing the flat panel display apparatus 100 includes a plurality of processes. A process of forming the sealing member 170 includes disposing a material for forming the sealing member 170, sintering and drying the material, and melting and curing the material.

In the melting process, two terminals of a power source 190 are connected to the inlets 180. If a voltage is applied, joule heat is generated from the wiring unit 150. The material for forming the sealing member 170, which overlaps the wiring unit 150, is easily melted and cured to form the sealing member 170. The sealing member 170 allows the substrate 101 and the sealing substrate 102 to be easily combined with each other.

In the flat panel display apparatus 100, the first protective layer 161 is disposed between the wiring unit 150 and the sealing member 170 to improve the bonding force between the wiring unit 150 and the sealing member 170. Thus, the combination between the substrate 101 and the sealing substrate 102 is enhanced. If the combination between the wiring unit 150 and the sealing member 170 is enhanced, heat generated from the wiring unit 150 may be effectively transferred to the sealing member 170 when power is applied to form the sealing member 170 in a process of manufacturing the flat panel display apparatus 100. The sealing member 170 may be formed with uniform characteristics. Thus, sealing characteristics of the flat panel display apparatus 100 may be improved.

The first protective layer 161 may be formed on the inlets 180 to easily prevent damage to the inlets 180. Thus, a current may be easily transferred to the wiring unit 150.

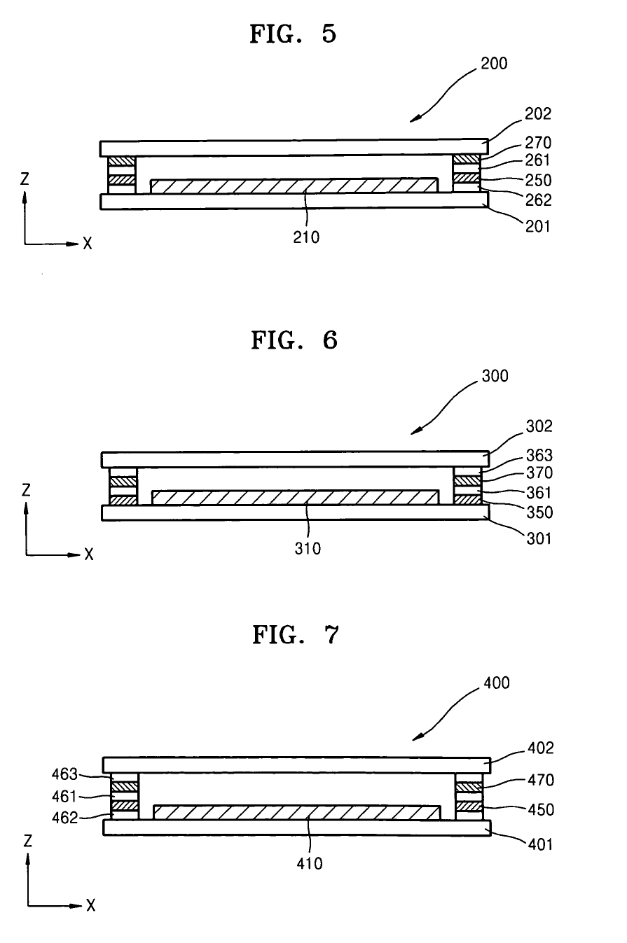

FIG. 5 is a cross-sectional view of a flat panel display apparatus 200 according to another embodiment.

Referring to FIG. 5, the flat panel display apparatus 200 includes a substrate 201, a display unit 210, a sealing substrate 202, a wiring unit 250, a sealing member 270, a first protective layer 261, a second protective layer 262, and inlets (not shown).

The display unit 210 is disposed on the substrate 201. The sealing substrate 202 is disposed to face the display unit 210. The sealing member 270 is disposed between the substrate 201 and the sealing substrate 202. The sealing member 270 is formed to surround the display unit 210. The sealing member 270 allows the substrate 201 and the sealing substrate 202 to be easily combined with each other. The sealing member 270 may include frit.

The wiring unit 250 is formed to overlap the sealing member 270. The wiring unit 250 is formed to surround the display unit 210. The wiring unit 250 may be formed of various conductive materials.

The first protective layer 261 is disposed between the wiring unit 250 and the sealing member 270. The first protective layer 261 includes an insulator, e.g., an oxide.

The first protective layer 261 is disposed between the wiring unit 250 and the sealing member 270 to allow the wiring unit 250 and the sealing member 270 to bond to each other. The first protective layer 261 protects and prevents damage to the wiring unit 250 during a high-temperature process for forming the sealing member 270.

The second protective layer 262 is formed between the substrate 201 and the wiring unit 250. The second protective layer 262 is disposed on the substrate 201. The wiring unit 250 is formed on the second protective layer 262. The first protective layer 261 is formed on the wiring unit 250. The sealing member 270 is formed on the first protective layer 261. The sealing substrate 202 is disposed on the sealing member 270.

The second protective layer 262 is disposed between the substrate 201 and the wiring unit 250 to prevent heat generated from the wiring unit 250 from being transferred to the substrate 201 when a voltage is applied to the wiring unit 250 to form the sealing member 270. The sealing member 270 is formed in a process of manufacturing the flat panel display apparatus 200. The second protective layer 262 allows the substrate 201 and the wiring unit 250 to be easily combined.

The second protective layer 262 is formed of the same material as the first protective layer 261.

Although not shown in FIG. 5, the inlets are formed to be connected to the wiring unit 250. The inlets are formed at ends of the wiring unit 250, similarly to the structure illustrated in FIG. 1.

The first protective layer 261 is disposed on the inlets. Thus, upper portions of the inlets are prevented from contacting and being oxidized due to moisture and air.

In the process of forming the sealing member 270, a voltage may be applied to the wiring unit 250 via the inlets to generate joule heat from the wiring unit 250. The material for forming the sealing member 270 may be melted and cured by the joule heat.

In the flat panel display apparatus 200, the first protective layer 261 is disposed between the wiring unit 250 and the sealing member 270 to improve the bonding force between the wiring unit 250 and the sealing member 270. The bonding force allows heat generated from the wiring unit 250 to be effectively transferred to the sealing member 270. The first protective layer 261 may be formed on the inlets to easily prevent damage to the inlets.

The flat panel display apparatus 200 includes the second protective layer 262 between the substrate 201 and the wiring unit 250 to allow the substrate 201 and the wiring unit 250 to be easily combined with each other. Thus, the flat panel display apparatus 200 has improved sealing characteristics. The second protective layer 262 prevents heat generated from the wiring unit 250 from being transferred to the substrate 201. Thus, the second protective layer 262 prevents a plurality of thin films and the display unit 210 formed on the substrate 201 from being damaged due to the heat.

FIG. 6 is a cross-sectional view of a flat panel display apparatus 300 according to another embodiment.

Referring to FIG. 6, the flat panel display apparatus 300 includes a substrate 301, a display unit 310, a sealing substrate 302, a wiring unit 350, a sealing member 370, a first protective layer 361, a third protective layer 363, and inlets (not shown).

The display unit 310 is disposed on the substrate 301. The sealing substrate 302 is disposed to face the display unit 310. The sealing member 370 is disposed between the substrate 301 and the sealing substrate 302. The sealing member 370 is formed to surround the display unit 310. The sealing member 370 allows the substrate 301 and the sealing substrate 302 to be easily combined with each other. The sealing member 370 may include frit.

The wiring unit 350 is formed to overlap the sealing member 370. The wiring unit 350 is formed to surround the display unit 310. The wiring unit 350 may be formed of various conductive materials.

The first protective layer 361 is disposed between the wiring unit 350 and the sealing member 370. The first protective layer 361 includes an insulator, e.g., an oxide. The first protective layer 361 is disposed between the wiring unit 350 and the sealing member 370 to allow the wiring unit 350 and the sealing member 370 to bond to each other. The first protective layer 361 protects and prevents damage to the wiring unit 350 during a high-temperature process for forming the sealing member 370.

The third protective layer 363 is formed between the sealing substrate 302 and the sealing member 370. The wiring unit 350 is disposed on the substrate 301, the first protective layer 361 is formed on the wiring unit 350, the sealing member 370 is formed on the first protective layer 361, the third protective layer 363 is formed on the sealing member 370, and the sealing substrate 302 is disposed on the third protective layer 363.

The third protective layer 363 may be formed of the same material as the first protective layer 361.

The third protective layer 363 is disposed between the sealing substrate 302 and the sealing member 370 to prevent heat generated from the wiring unit 350 from being transferred to the sealing substrate 302. Heat generated from the wiring unit 350 occurs when a voltage is applied to the wiring unit 350 to form the sealing member 370. The forming of the sealing member 370 occurs in a process of manufacturing the flat panel display apparatus 300. The third protective layer 363 enhances the combination between the sealing substrate 302 and the sealing member 370.

Although not shown in FIG. 6, the inlets are formed to connect to the wiring unit 350. The inlets are formed at ends of the wiring unit 350, similarly to the structure illustrated in FIG. 1.

The first protective layer 361 is also disposed on the inlets. As such, the inlets are prevented from contacting and being oxidized due to moisture and air.

In the process of forming the sealing member 370, a voltage may be applied to the wiring unit 350. The voltage may be applied to the wiring unit 350 via the inlets to generate joule heat from the wiring unit 350. The material for forming the sealing member 370 may be melted and then cured by the joule heat.

In the flat panel display apparatus 300, the first protective layer 361 is disposed between the wiring unit 350 and the sealing member 370. The first protective layer 361 enhances the combination between the wiring unit 350 and the sealing member 370, and allows heat generated from the wiring unit 350 to be effectively transferred to the sealing member 370. The first protective layer 361 may be formed on the inlets to prevent damage to the inlets.

The flat panel display apparatus 300 includes the third protective layer 363 between the sealing substrate 302 and the sealing member 370 to allow the sealing substrate 302 and the sealing member 370 to be combined with each other. Thus, sealing characteristics of the flat panel display apparatus 300 are improved. The third protective layer 363 prevents heat generated from the wiring unit 350 from being transferred to the sealing substrate 302. Thus, the sealing substrate 302 is prevented from being damaged by the heat.

FIG. 7 is a cross-sectional view of a flat panel display apparatus 400 according to another embodiment.

Referring to FIG. 7, the flat panel display apparatus 400 includes a substrate 401, a display unit 410, a sealing substrate 402, a wiring unit 450, a sealing member 470, a first protective layer 461, a second protective layer 462, a third protective layer 463, and inlets (not shown).

The display unit 410 is disposed on the substrate 401. The sealing substrate 402 is disposed to face the display unit 410. The sealing member 470 is disposed between the substrate 401 and the sealing substrate 402. The sealing member 470 is formed to surround the display unit 410. The sealing member 470 allows the substrate 401 and the sealing substrate 402 to be easily combined with each other. The sealing member 470 may include frit.

The wiring unit 450 is formed to overlap the sealing member 470. The wiring unit 450 is formed to surround the display unit 410. The wiring unit 450 may be formed of various conductive materials.

The first protective layer 461 is disposed between the wiring unit 450 and the sealing member 470. The first protective layer 461 includes an insulator, e.g., an oxide.

The second protective layer 462 is formed between the substrate 401 and the wiring unit 450. The second protective layer 462 may include various materials. The second protective layer 462 may be formed of the same material as the first protective layer 461.

The third protective layer 463 is formed between the sealing substrate 402 and the sealing member 470. The second protective layer 462 is formed on the substrate 401. The wiring unit 450 is disposed on the second protective layer 462. The first protective layer 461 is formed on the wiring unit 450. The sealing member 470 is formed on the first protective layer 461. The third protective layer 463 is formed on the sealing member 470. The sealing substrate 402 is disposed on the third protective layer 463.

The third protective layer 463 may include various materials and may be formed from the same material as the first protective layer 461.

The first protective layer 461 is disposed between the wiring unit 450 and the sealing member 470 to allow the wiring unit 450 and the sealing member 470 to bond to each other. The first protective layer 461 protects and prevents damage to the wiring unit 450 during a high-temperature process for forming the sealing member 470.

The second protective layer 462 is disposed between the substrate 401 and the wiring unit 450 to prevent heat generated from the wiring unit 450 from being transferred to the substrate 401. Heat generated from the wiring unit 450 occurs when a voltage is applied to the wiring unit 450 to form the sealing member 470. Forming the sealing member 470 occurs in a process of manufacturing the flat panel display apparatus 400. Also, the second protective layer 462 enhances the combination between the substrate 401 and the wiring unit 450.

The third protective layer 463 is disposed between the sealing substrate 402 and the sealing member 470 to prevent heat generated from the wiring unit 450 from being transferred to the sealing substrate 402. Heat generated from the wiring unit 450 occurs when a voltage is applied to the wiring unit 450 to form the sealing member 470. Forming the sealing member 470 occurs in a process of manufacturing the flat panel display apparatus 400. The third protective layer 463 enhances the combination between the sealing substrate 402 and the sealing member 470.

Although not shown in FIG. 6, the inlets are formed to connect to the wiring unit 450. The inlets are formed at ends of the wiring unit 450, similarly to the structure illustrated in FIG. 1.

The first protective layer 461 is also disposed on the inlets. Upper portions of the inlets are prevented from contacting and being oxidized due to moisture and air.

In the process of forming the sealing member 470, a voltage may be applied to the wiring unit 450. The voltage may be applied to the wiring unit 450 via the inlets to generate joule heat from the wiring unit 450. The material for forming the sealing member 470 may be melted and then cured by the joule heat.

In the flat panel display apparatus 400, the first protective layer 461 is disposed between the wiring unit 450 and the sealing member 470. The first protective layer 461 enhances the combination between the wiring unit 450 and the sealing member 470 and allows heat generated from the wiring unit 450 to be effectively transferred to the sealing member 470. The first protective layer 461 may be formed on the inlets to prevent damage to the inlets.

The flat panel display apparatus 400 includes the second protective layer 462 between the substrate 401 and the wiring unit 450. The second protective layer 462 enhances the combination between the substrate 401 and the wiring unit 450. Thus, the sealing characteristics of the flat panel display apparatus 400 are improved. The second protective layer 462 prevents heat generated from the wiring unit 450 from being transferred to the substrate 401. Thus, the second protective layer 462 prevents a plurality of thin films and the display unit 410 from being damaged due to the heat. The display unit 410 is formed on the substrate 401.

The flat panel display apparatus 400 includes the third protective layer 463 between the sealing substrate 402 and the sealing member 470. The third protective layer 463 allows the sealing substrate 402 and the sealing member 470 to be easily combined with each other. Thus, the sealing characteristics of the flat panel display apparatus 400 are improved. The third protective layer 463 prevents heat generated from the wiring unit 450 from being transferred to the sealing substrate 402. Thus, the third protective layer 463 prevents the sealing substrate 402 from being damaged by the heat.

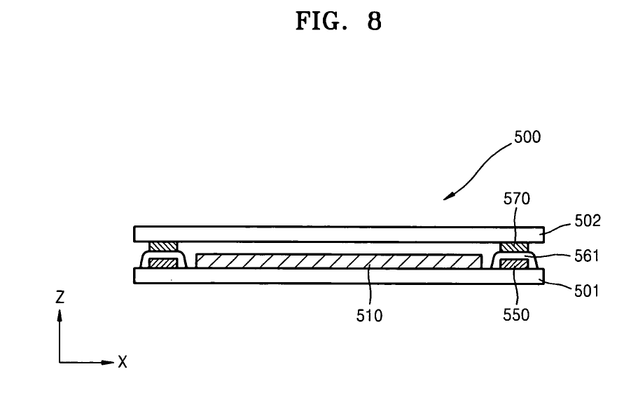

FIG. 8 is a cross-sectional view of a flat panel display apparatus 500 according to another embodiment.

Referring to FIG. 8, the flat panel display apparatus 500 includes a substrate 501, a display unit 510, a sealing substrate 502, a wiring unit 550, a sealing member 570, a first protective layer 561, and inlets (not shown).

The display unit 510 is disposed on the substrate 501. The display unit 510 may be of various types. The sealing substrate 502 is disposed to face the display unit 510. The sealing member 570 is disposed between the substrate 501 and the sealing substrate 502. The sealing member 570 is formed to surround the display unit 510. The sealing member 570 allows the substrate 501 and the sealing substrate 502 to be easily combined with each other. The sealing member 570 may include frit.

The wiring unit 550 is formed to overlap the sealing member 570. The wiring unit 550 is formed to surround the display unit 510. The wiring unit 550 may be formed of various conductive materials.

The first protective layer 561 is disposed between the wiring unit 550 and the sealing member 570. The wiring unit 550 is formed on the substrate 501. The first protective layer 561 is formed on the wiring unit 550. The sealing member 570 is formed on the first protective layer 561. The sealing substrate 502 is disposed on the sealing member 570.

The first protective layer 561 is formed to correspond to side surfaces of the wiring unit 550. The first protective layer 561 extends in an X-direction of FIG. 8, covers the side surfaces of the wiring unit 550, and contacts the substrate 501.

The first protective layer 561 includes an insulator, e.g., an oxide.

The first protective layer 561 is disposed between the wiring unit 550 and the sealing member 570 to allow the wiring unit 550 and the sealing member 570 to bond to each other.

After a material, e.g., frit, for forming the sealing member 570 is disposed and formed, a drying and sintering process is performed at a high temperature. The first protective layer 561 protects and prevents damage to the wiring unit 550 during the high-temperature process. The first protective layer 561 prevents the wiring unit 550 from being damaged due to high-temperature heat transferred from the side surfaces of the wiring unit 550.

The first protective layer 561 is formed to correspond to the side surfaces of the wiring unit 550 so as to prevent damage to the side surfaces of the wiring unit 550. The first protective layer 561 contacts the substrate 501 and covers the side surfaces of the wiring unit 550. The first protective layer 561 prevents penetration of moisture and impurities through the side surfaces of the wiring unit 550. Thus, the first protective layer 561 prevents oxidation or other damage to the wiring unit 550.

Although not shown in FIG. 5, the inlets are formed to be connected to the wiring unit 550. The inlets are formed at ends of the wiring unit 550, similarly to the structure illustrated in FIG. 1.

The first protective layer 561 is disposed on the inlets. The inlets are prevented from contacting and being oxidized due to moisture and air.

In the process of forming the sealing member 570, a voltage may be applied to the wiring unit 550. The voltage may be applied to the wiring unit 550 via the inlets to generate joule heat from the wiring unit 550. The material for forming the sealing member 570 may be melted and then cured by the joule heat.

In the flat panel display apparatus 500, the first protective layer 561 is disposed between the wiring unit 550 and the sealing member 570. The first protective layer improves the bonding force between the wiring unit 550 and the sealing member 570. The first protective layer 461 allows heat generated from the wiring unit 550 to be effectively transferred to the sealing member 570. The first protective layer 561 may be formed on the inlets to prevent damage to the inlets.

The first protective layer 561 is formed to correspond to the side surfaces of the wiring unit 550. The first layer 561 prevents oxidation of the wiring unit 550 through the side surfaces of the wiring unit 550. The first protective layer 561 is formed to improve the combination between the substrate 501 and the first protective layer 561. The first protective layer 561 enhances the combination between the substrate 501 and the sealing substrate 502. Thus, the first protective layer 561 improves sealing characteristics of the flat panel display apparatus 500. The first protective layer 561 is formed to contact the substrate 501.

According to the embodiments described above, sealing characteristics of a flat panel display apparatus may be easily improved.

Exemplary embodiments of the inventive concept have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the inventive concept as set forth in the following claims.

What is claimed is:

1. A flat panel display apparatus, comprising:
a substrate;
a display unit disposed on the substrate;
a sealing substrate disposed to face the display unit;
a sealing member disposed between the substrate and the sealing substrate to surround the display unit;
a wiring unit disposed between the substrate and the sealing substrate to overlap the sealing member;
a first protective layer disposed between the sealing member and the wiring unit; and
inlets formed to be electrically connected to an external power source, wherein the inlets apply a voltage to the wiring unit.

2. The flat panel display apparatus as claimed in claim 1, further comprising a second protective layer disposed between the substrate and the wiring unit.

3. The flat panel display apparatus as claimed in claim 1, further comprising a third protective layer disposed between the sealing substrate and the sealing member.

4. The flat panel display apparatus as claimed in claim 1, wherein the first protective layer is formed to correspond to side surfaces of the wiring unit.

5. The flat panel display apparatus as claimed in claim 4, wherein the first protective layer extends to contact the substrate.

6. The flat panel display apparatus as claimed in claim 1, wherein the first protective layer extends to be disposed on the inlets.

7. The flat panel display apparatus as claimed in claim 1, wherein the wiring unit is formed on the substrate, and
wherein the sealing member is disposed between the wiring unit and the sealing substrate.

8. The flat panel display apparatus as claimed in claim 1, wherein the sealing member comprises frit.

9. The flat panel display apparatus as claimed in claim 1, wherein the display unit comprises an organic light emitting device.

10. A method of manufacturing a flat panel display apparatus, the method comprising:
preparing a substrate;
disposing a display unit on the substrate;
disposing a sealing substrate to face the display unit;
forming a sealing member between the substrate and the sealing substrate to surround the display unit;
disposing a wiring unit between the substrate and the sealing substrate to overlap the sealing member;
disposing a first protective layer between the sealing member and the wiring unit; and
forming inlets to be electrically connected to an external power source and the wiring unit to apply a voltage to the wiring unit,
wherein the forming of the sealing member comprises:
disposing a material for forming the sealing member between the substrate and the sealing substrate;
electrically connecting the inlets to the power source;
applying a voltage from the power source to the wiring unit to generate heat from the wiring unit; and
melting and curing the sealing member by using the generated heat.

11. The method as claimed in claim 10, wherein forming the sealing member comprises frit.
